(19) United States
(12) Patent Application Publication
(10) Pub. No.: US 2024/0194696 A1
(43) Pub. Date: Jun. 13, 2024

(54) GATE CONTROL FOR STAGGERED STACKED FIELD-EFFECT TRANSISTORS

(71) Applicant: International Business Machines Corporation, Armonk, NY (US)

(72) Inventors: Genevieve Antoinette Kane, Albany, NY (US); Manasa Medikonda, Albany, NY (US); Md Nabil Azad, Malta, NY (US); Shravana Kumar Katakam, Lehi, UT (US); Nicholas Latham, Albany, NY (US); Indira Seshadri, Niskayuna, NY (US); Tao Li, Slingerlands, NY (US)

(21) Appl. No.: 18/077,374

(22) Filed: Dec. 8, 2022

(51) Int. Cl. H01L 27/12

(52) U.S. Cl. CPC H01L 27/1248; H01L 27/1222; H01L 27/124; H01L 27/1266; H01L 27/127

(57) ABSTRACT

A semiconductor device includes a first transistor comprising a first gate region, and a second transistor comprising a second gate region. The second transistor is stacked on the first transistor in a staggered configuration. A dielectric bonding layer is between the first transistor and the second transistor, and a gate cut portion is along a side of the first gate region and a side of the second gate region. A gate contact is connected to at least one of the first gate region and the second gate region.

### BACKGROUND

The present application relates to semiconductors, and more specifically, to techniques for forming semiconductor structures. Semiconductors and integrated circuit chips have become ubiquitous within many products, particularly as they continue to decrease in cost and size. There is a continued desire to reduce the size of structural features and/or to provide a greater amount of structural features for a given chip size. Miniaturization, in general, allows for increased performance at lower power levels and lower cost. Present technology is at or approaching atomic level scaling of certain micro-devices such as logic gates, field-effect transistors (FETs), and capacitors.

### SUMMARY

Embodiments of the invention provide techniques for forming contact structures for a stacked semiconductor device.

In one embodiment, a semiconductor device includes a first transistor comprising a first gate region, and a second transistor comprising a second gate region. The second transistor is stacked on the first transistor in a staggered configuration. A dielectric bonding layer is between the first transistor and the second transistor, and a gate cut portion is along a side of the first gate region and a side of the second gate region. A gate contact is connected to at least one of the first gate region and the second gate region.

In another embodiment, a semiconductor device includes a first pair of transistors and a second pair of transistors. The first pair of transistors comprises a second transistor stacked on a first transistor in a staggered configuration, and the second pair of transistors comprises a fourth transistor stacked on a third transistor in a staggered configuration. The first transistor comprises a first gate region, the second transistor comprises a second gate region, the third transistor comprises a third gate region and the fourth transistor comprises a fourth gate region. A first gate contact is electrically connected to the first gate region and the second gate region, a second gate contact is electrically connected to the third gate region, and a third gate contact is electrically connected to the fourth gate region.

In another embodiment, a semiconductor device includes a first transistor comprising a first gate region, and a second transistor comprising a second gate region. The second transistor is stacked on the first transistor in a staggered configuration. A dielectric bonding layer is between the first transistor and the second transistor, and a dielectric trench is along a side of the first gate region and a side of the second gate region. At least one gate contact contacts one of the first gate region and the second gate region.

These and other features and advantages of embodiments described herein will become more apparent from the accompanying drawings and the following detailed description.

### BRIEF DESCRIPTION OF THE DRAWINGS

FIG. 1A is a schematic top view of a semiconductor structure, according to an embodiment of the invention.

FIG. 1B is a schematic cross-sectional view taken along a first axis and illustrating the semiconductor structure of FIG. 1A, according to an embodiment of the invention.

FIG. 1C is a schematic cross-sectional view taken along a second axis and illustrating the semiconductor structure of FIG. 1A, according to an embodiment of the invention.

FIG. 1D is a schematic cross-sectional view taken along a third axis and illustrating the semiconductor structure of FIG. 1A, according to an embodiment of the invention.

FIG. 2A is a schematic top view illustrating formation of gate cut portions in the semiconductor structure of FIG. 1A, according to an embodiment of the invention.

FIG. 2B is a schematic cross-sectional view taken along the second axis and illustrating formation of gate cut portions in the semiconductor structure of FIG. 1C, according to an embodiment of the invention.

FIG. 3A is a schematic cross-sectional view taken along the first axis and illustrating formation of a bonding oxide on and wafer bonding to the semiconductor structure following formation of the gate cut portions, according to an embodiment of the invention.

FIG. 3B is a schematic cross-sectional view taken along the second axis and illustrating formation of a bonding oxide on and wafer bonding to the semiconductor structure following formation of the gate cut portions, according to an embodiment of the invention.

FIG. 3C is a schematic cross-sectional view taken along the third axis and illustrating formation of a bonding oxide on and wafer bonding to the semiconductor structure following formation of the gate cut portions, according to an embodiment of the invention.

FIG. 4A is a schematic cross-sectional view taken along the first axis and illustrating wafer grinding on and semiconductor layer removal from the semiconductor structure of FIG. 3A, according to an embodiment of the invention.

FIG. 4B is a schematic cross-sectional view taken along the second axis and illustrating wafer grinding on and semiconductor layer removal from the semiconductor structure of FIG. 3B, according to an embodiment of the invention.

FIG. 4C is a schematic cross-sectional view taken along the third axis and illustrating wafer grinding on and semiconductor layer removal from the semiconductor structure of FIG. 3C, according to an embodiment of the invention.

FIG. 5A is a schematic top view illustrating active area patterning following wafer grinding and semiconductor layer removal, according to an embodiment of the invention.

FIG. 5B is a schematic cross-sectional view taken along the second axis and illustrating active area patterning following wafer grinding and semiconductor layer removal, according to an embodiment of the invention.

FIG. 5C is a schematic cross-sectional view taken along the third axis and illustrating active area patterning following wafer grinding and semiconductor layer removal, according to an embodiment of the invention.

FIG. 6A is a schematic cross-sectional view taken along the first axis and illustrating top transistor structure and inter-layer dielectric (ILD) layer formation following active area patterning, according to an embodiment of the invention.

FIG. 6B is a schematic cross-sectional view taken along the second axis and illustrating top transistor structure and ILD layer formation following active area patterning, according to an embodiment of the invention.

FIG. 6C is a schematic cross-sectional view taken along the third axis and illustrating top transistor structure and ILD layer formation following active area patterning, according to an embodiment of the invention.

FIG. 7 is a schematic cross-sectional view taken along the second axis and illustrating top dummy gate cut patterning and sacrificial layer removal following top transistor structure and ILD layer formation, according to an embodiment of the invention.

FIG. 8A is a schematic cross-sectional view taken along the first axis and illustrating dummy gate and semiconductor layer removal following top dummy gate cut patterning and sacrificial layer removal, according to an embodiment of the invention.

FIG. 8B is a schematic cross-sectional view taken along the second axis and illustrating dummy gate and semiconductor layer removal following top dummy gate cut patterning and sacrificial layer removal, according to an embodiment of the invention.

FIG. 9A is a schematic cross-sectional view taken along the first axis and illustrating replacement metal gate formation following dummy gate and semiconductor layer removal, according to an embodiment of the invention.

FIG. 9B is a schematic cross-sectional view taken along the second axis and illustrating replacement metal gate formation following dummy gate and semiconductor layer removal, according to an embodiment of the invention.

FIG. 10 is a schematic cross-sectional view taken along the second axis and illustrating formation of gate cut portions following replacement metal gate formation, according to an embodiment of the invention.

FIG. 11A is a schematic top view illustrating contact patterning following formation of gate cut portions, according to an embodiment of the invention.

FIG. 11B is a schematic cross-sectional view taken along the first axis and illustrating contact patterning following formation of gate cut portions, according to an embodiment of the invention.

FIG. 11C is a schematic cross-sectional view taken along the second axis and illustrating contact patterning following formation of gate cut portions, according to an embodiment of the invention.

FIG. 11D is a schematic cross-sectional view taken along the third axis and illustrating contact patterning following formation of gate cut portions, according to an embodiment of the invention.

FIG. 12A is a schematic cross-sectional view taken along the first axis and illustrating contact metallization, back-end-of-line (BEOL) formation and carrier wafer bonding following contact patterning, according to an embodiment of the invention.

FIG. 12B is a schematic cross-sectional view taken along the second axis and illustrating contact metallization, BEOL formation and carrier wafer bonding following contact patterning, according to an embodiment of the invention.

FIG. 12C is a schematic cross-sectional view taken along the third axis and illustrating contact metallization, BEOL formation and carrier wafer bonding following contact patterning, according to an embodiment of the invention.

FIG. 13A is a schematic cross-sectional view taken along the first axis and illustrating semiconductor structure rotation, substrate, etch stop layer and semiconductor layer removal and backside inter-layer dielectric (ILD) layer deposition following contact metallization, BEOL formation and carrier wafer bonding, according to an embodiment of the invention.

FIG. 13B is a schematic cross-sectional view taken along the second axis and illustrating semiconductor structure rotation, substrate, etch stop layer and semiconductor layer removal and backside ILD layer deposition following contact metallization, BEOL formation and carrier wafer bonding, according to an embodiment of the invention.

FIG. 13C is a schematic cross-sectional view taken along the third axis and illustrating semiconductor structure rotation, substrate, etch stop layer and semiconductor layer removal and backside ILD layer deposition following contact metallization, BEOL formation and carrier wafer bonding, according to an embodiment of the invention.

FIG. 14A is a schematic cross-sectional view taken along the first axis and illustrating backside contact and power delivery network layer formation on the FIG. 13A structure, according to an embodiment of the invention.

FIG. 14B is a schematic cross-sectional view taken along the second axis and illustrating backside contact and power delivery network layer formation on the FIG. 13B structure, according to an embodiment of the invention.

FIG. 14C is a schematic cross-sectional view taken along the third axis and illustrating backside contact and power delivery network layer formation on the FIG. 13C structure, according to an embodiment of the invention.

### DETAILED DESCRIPTION

Illustrative embodiments of the invention may be described herein in the context of illustrative methods for forming contact structures for a stacked semiconductor device where configurations of gate cut portions and dielectric layers control gate contact connections to gate regions of stacked transistors, along with illustrative apparatus, systems and devices formed using such methods. However, it is to be understood that embodiments of the invention are not limited to the illustrative methods, apparatus, systems and devices but instead are more broadly applicable to other suitable methods, apparatus, systems and devices.

It is to be understood that the various features shown in the accompanying drawings are schematic illustrations that are not necessarily drawn to scale. Moreover, the same or similar reference numbers may be used throughout the drawings to denote the same or similar features, elements, or structures, and thus, a detailed explanation of the same or similar features, elements, or structures will not be repeated for each of the drawings. Further, the terms “exemplary” and “illustrative” as used herein mean “serving as an example, instance, or illustration.” Any embodiment or design described herein as “exemplary” or “illustrative” is not to be construed as preferred or advantageous over other embodiments or designs.

A field-effect transistor (FET) is a transistor having a source, a gate, and a drain, and having action that depends on the flow of carriers (electrons or holes) along a channel that runs between the source and drain. Current through the channel between the source and drain may be controlled by a transverse electric field under the gate.

FETs are widely used for switching, amplification, filtering, and other tasks. FETs include metal-oxide-semiconductor (MOS) FETs (MOSFETs). Complementary MOS (CMOS) devices are widely used, where both n-type and p-type transistors (nFET and pFET) are used to fabricate logic and other circuitry. Source and drain regions of a FET are typically formed by adding dopants to target regions of a semiconductor body on either side of a channel, with the gate being formed above the channel. The gate includes a gate dielectric over the channel and a gate conductor over the gate dielectric. The gate dielectric is an insulator material that prevents large leakage current from flowing into the channel when voltage is applied to the gate conductor while allowing applied gate voltage to produce a transverse electric field in the channel.

Various techniques may be used to reduce the size of FETs. One technique is through the use of fin-shaped channels in FinFET devices. Before the advent of FinFET arrangements, CMOS devices were typically substantially planar along the surface of the semiconductor substrate, with the exception of the FET gate disposed over the top of the channel. FinFETs utilize a vertical channel structure, increasing the surface area of the channel exposed to the gate. Thus, in FinFET structures the gate can more effectively control the channel, as the gate extends over more than one side or surface of the channel. In some FinFET arrangements, the gate encloses three surfaces of the three-dimensional channel, rather than being disposed over just the top surface of a traditional planar channel.

Another technique useful for reducing the size of FETs is through the use of stacked nanosheet channels formed over a semiconductor substrate. Stacked nanosheets may be two-dimensional nanostructures, such as sheets having a thickness range on the order of 1 to 100 nanometers (nm). Nanosheets and nanowires are viable options for scaling to 7 nm and beyond. A general process flow for formation of a nanosheet stack involves selectively removing sacrificial layers, which may be formed of silicon germanium (SiGe), between sheets of channel material, which may be formed of silicon (Si).

For continued scaling (e.g., to 2.5 nm and beyond), next-generation complementary FET (CFET) devices may be used. CFET devices provide a complex gate-all-around (GAA) structure. Conventional GAA FETs, such as nanosheet FETs, may stack multiple p-type nanowires or nanosheets on top of each other in one device, and may stack multiple n-type nanowires or nanosheets on top of each other in another device. CFET structures provide improved track height scaling, leading to structural gains (e.g., such as 30-40% structural gains for different types of devices, such as logic devices, static random-access memory (SRAM) devices, etc.). In CFET structures, n-type and p-type nanowires or nanosheets are stacked on each other, eliminating n-to-p separation bottlenecks and reducing the device area footprint. There is, however, a continued to desire for further scaling and reducing the size of FETs.

As discussed above, various techniques may be used to reduce the size of FETs, including through the use of fin-shaped channels in FinFET devices, through the use of stacked nanosheet channels formed over a semiconductor substrate, and next-generation CFET devices.

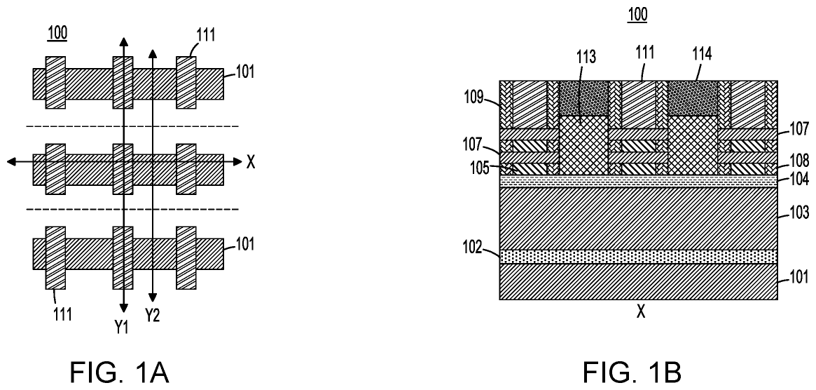

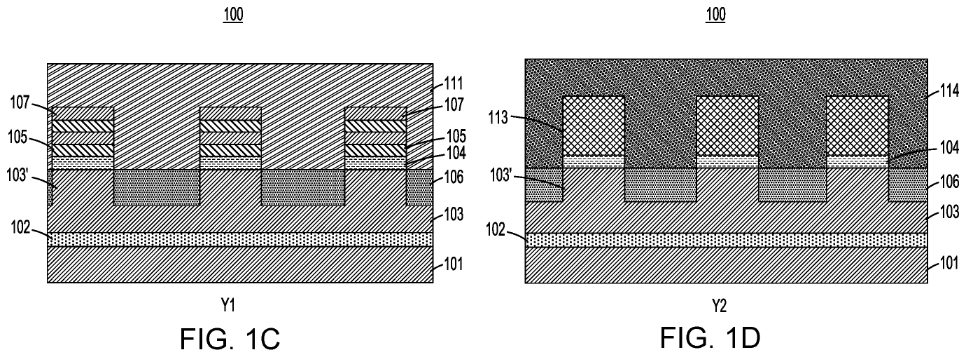

As used herein, “frontside” refers to a side on top of a semiconductor substrate 101 in the orientation shown in FIGS. 1B-1D, 2B-4C, 5B-10 and 11B-12C. In some instances, the phrase “first side” may be used to refer to a “frontside.”

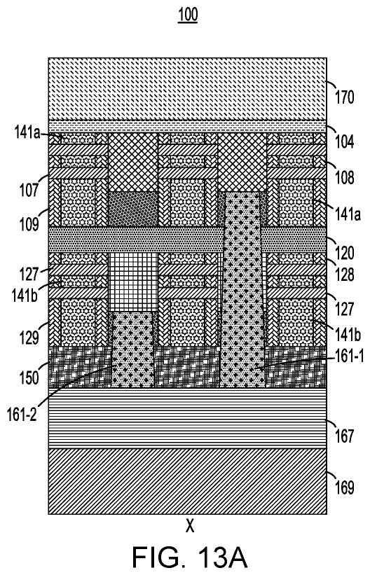

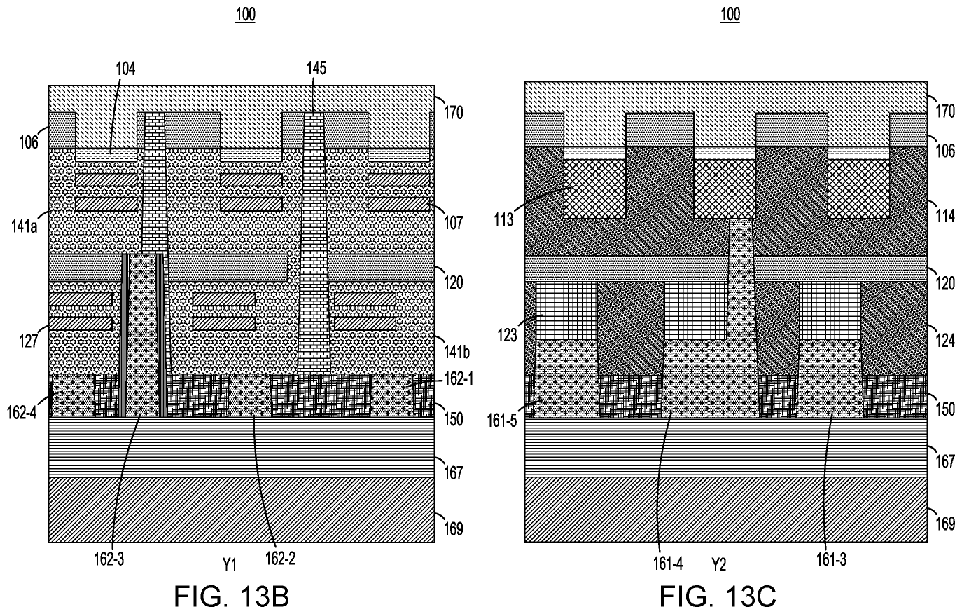

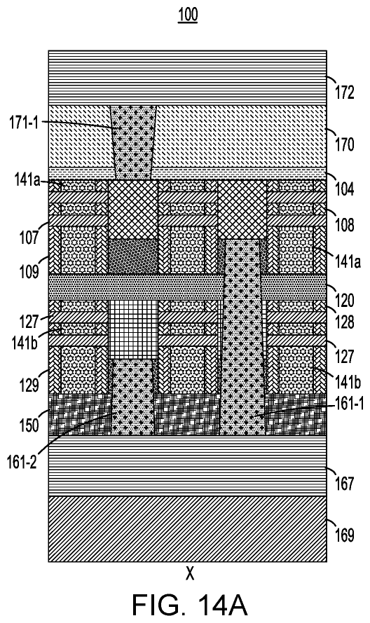

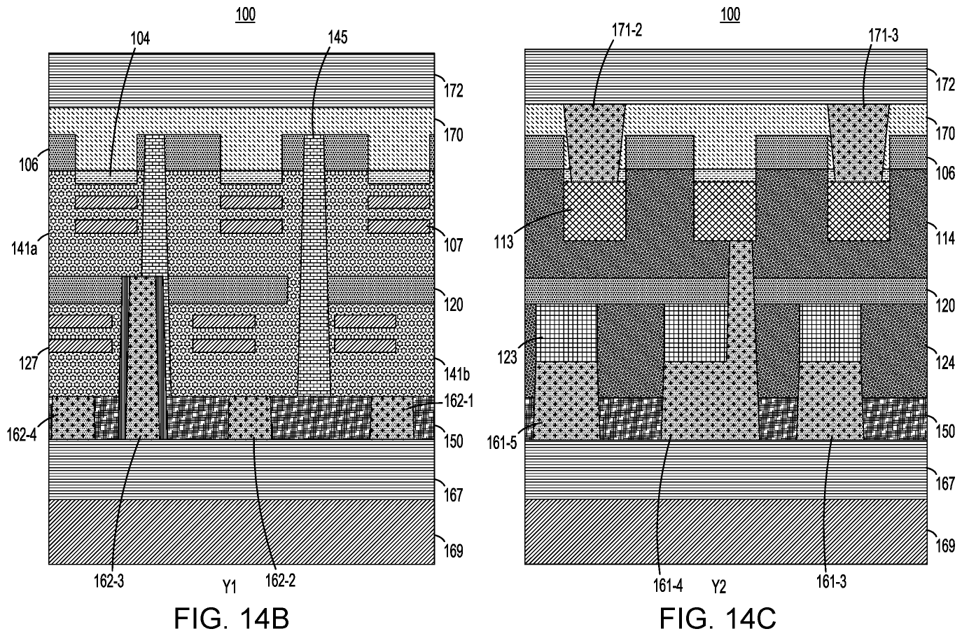

As used herein, “backside” refers to a side opposite the “frontside” (e.g., a top side of the flipped semiconductor structure 100 in FIGS. 13A-14C as opposed to the bottom side in FIGS. 13A-14C). In some instances, the phrase “second side” may be used to refer to a “frontside.”

FIG. 1A is a schematic top view of a semiconductor structure 100. FIG. 1B is a schematic cross-sectional view taken along a first axis (X-axis), FIG. 1C is a schematic cross-sectional view taken along a second axis (Y1-axis), and FIG. 1D is a schematic cross-sectional view taken along a third axis (Y2-axis) and illustrating the semiconductor structure 100 of FIG. 1A. Referring to FIGS. 1B-1D, a semiconductor substrate 101 comprises semiconductor material including, but not limited to, silicon (Si), III-V, II-V compound semiconductor materials or other like semiconductor materials. In addition, multiple layers of the semiconductor materials can be used as the semiconductor material of the semiconductor substrate 101. An etch stop layer 102 is formed on the semiconductor substrate 101, and may comprise, for example, silicon oxide (SiOₓ) (where x is for example, 2, 1.99 or 2.01), or silicon germanium (SiGe). A semiconductor layer 103 comprising, for example, the same semiconductor material as the semiconductor substrate 101, or other like semiconductor material, is formed on the etch stop layer 102.

In accordance with an embodiment of the present invention, a dielectric layer 104 (also referred to as a bottom dielectric insulator (BDI) layer) is formed on the semiconductor layer 103. The dielectric layer 104 may comprise, for example, silicon nitride (SiN), silicon oxynitride (SiON), silicon-carbon-nitride (SiCN), boron nitride (BN), silicon boron nitride (SiBN), silicoboron carbonitride (SiBCN), silicon oxycarbonitride (SiOCN) and combinations thereof, and is deposited using deposition techniques such as, for example, chemical vapor deposition (CVD), plasma enhanced CVD (PECVD), radio-frequency CVD (RFCVD), physical vapor deposition (PVD), atomic layer deposition (ALD), molecular beam deposition (MBD), pulsed laser deposition (PLD), and/or liquid source misted chemical deposition (LSMCD).

Layers of silicon germanium (SiGe), and of silicon (Si) are stacked in an alternating configuration on the dielectric layer 104, so that a first SiGe layer is followed by a first Si layer on the first SiGe layer, which is followed by a second SiGe layer on the first Si layer, and so on. As can be understood, SiGe layers and Si layers are epitaxially grown. The stacked nanosheet layers of SiGe layers and Si layers are patterned into nanosheet stacks comprising SiGe layers 105 and Si layers 107 as shown in FIGS. 1B and 1C. While two SiGe layers 105 and two Si layers 107 are shown, the embodiments of the present invention are not necessarily limited to the shown number of layers 105, 107, and there may be more or less layers in the same alternating configuration depending on design constraints. For ease of explanation, three nanosheet stacks are shown. However, the embodiments are not limited thereto, and more or less than three nanosheet stacks can be formed. Referring to FIGS. 1C and 1D, portions of the semiconductor layer 103 are etched during the patterning to form pedestal portions 103′ from part of the semiconductor layer 103. Another dielectric layer 106 fills in recessed portions of the semiconductor layer 103 between the pedestal portions 103′ to form isolation regions (e.g., shallow trench isolation (STI) regions). The dielectric layer 106 comprises, for example, an oxide such as, but not necessarily limited to, SiOₓ or other suitable dielectric materials.

The SiGe layers 105 are also referred to herein as sacrificial semiconductor layers since, as described further herein, the SiGe layers 105 are eventually removed and replaced by gate structures. Although SiGe is described as a sacrificial material for SiGe layers 105, and Si is described as a nanosheet channel material for Si layers 107, other materials can be used, as long as the sacrificial semiconductor layers have the property of being able to be removed selectively compared to the nanosheet channel material.

The terms “epitaxial growth and/or deposition” and “epitaxially formed and/or grown,” mean the growth of a semiconductor material (crystalline material) on a deposition surface of another semiconductor material (crystalline material), in which the semiconductor material being grown (crystalline over layer) has substantially the same crystalline characteristics as the semiconductor material of the deposition surface (seed material). In an epitaxial deposition process, the chemical reactants provided by the source gases are controlled, and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed.

The epitaxial deposition process may employ the deposition chamber of a chemical vapor deposition type apparatus, such as a rapid thermal chemical vapor deposition (RTCVD), ultra-high vacuum chemical vapor deposition (UHVCVD), or a low-pressure chemical vapor deposition (LPCVD) apparatus. A number of different sources may be used for the epitaxial deposition of the in situ doped semiconductor material. In some embodiments, the gas source for the deposition of an epitaxially formed semiconductor material may include silicon (Si) deposited from silane, disilane, trisilane, tetrasilane, hexachlorodisilane, tetrachlorosilane, dichlorosilane, trichlorosilane, and combinations thereof. In other examples, when the semiconductor material includes germanium, a germanium gas source may be selected from the group consisting of germane, digermane, halogermane, dichlorogermane, trichlorogermane, tetrachlorogermane and combinations thereof. The temperature for epitaxial deposition typically ranges from 450° C. to 900° C. Although higher temperature typically results in faster deposition, the faster deposition may result in crystal defects and film cracking.

Bottom dummy gate portions 111 are formed on the uppermost Si layers 107 and around the stacked nanosheet configurations of the SiGe layers 105 and Si layers 107. The bottom dummy gate portions 111 include, but are not necessarily limited to, an amorphous silicon (a-Si) layer. The bottom dummy gate portions 111 are deposited using deposition techniques such as, for example, CVD, PECVD, RFCVD, PVD, ALD, MBD, PLD, LSMCD, sputtering and/or plating, followed by a planarization process, such as, chemical mechanical planarization (CMP), and lithography and etching steps to remove excess dummy gate material, and pattern the deposited layer.

Referring to FIG. 1B, due to the germanium in SiGe layers 105, lateral etching of the SiGe layers 105 can be performed selective to Si layers 107, such that the side portions of the SiGe layers 105 can be removed to create vacant areas to be filled in by inner spacers 108. The material of the inner spacers 108 can comprise, but is not necessarily limited to, a nitride, such as, SiN, SiON, SiCN, BN, SiBN, SiBCN or SiOCN. Gate spacers 109 are positioned on the nanosheet stacks on opposite lateral sides of the bottom dummy gate portions 111. The gate spacers 109 are formed from the same or similar material to that of the inner spacers 108. The inner and gate spacers 108 and 109 can be formed by any suitable techniques such as deposition followed by directional etching. Deposition may include, but is not limited to, ALD or CVD. Directional etching may include but is not limited to, reactive ion etching (RIE).

Bottom source/drain regions 113 comprise epitaxial layers grown from sides of the Si layers 107. According to a non-limiting embodiment of the present invention, the conditions of the epitaxial growth process for the bottom source/drain regions 113 are, for example, RTCVD epitaxial growth using SiH₄, SiH₂Cl₂, GeH₄, CH₃SiH₃, B₂H₆, PF₃, and/or H₂ gases with temperature and pressure range of about 450° C. to about 800° C., and about 5 Torr-about 300 Torr. While embodiments of the present invention may be described in connection with source/drain regions for a n-type FET (nFET) comprising, for example, Si source/drain regions, the embodiments are not necessarily limited thereto. The embodiments can also be used in connection with the formation of source/drain regions for p-type FETs (pFETs) comprising, for example, silicon germanium source/drain regions.

The bottom source/drain regions 113 may be suitably doped, such as by using ion implantation, gas phase doping, plasma doping, plasma immersion ion implantation, cluster doping, infusion doping, liquid phase doping, solid phase doping, etc. N-type dopants may be selected from a group of phosphorus (P), arsenic (As) and antimony (Sb), and p-type dopants may be selected from a group of boron (B), boron fluoride (BF₂), gallium (Ga), indium (In), and thallium (TI).

In non-limiting illustrative embodiments, the bottom source/drain regions 113 can comprise in-situ phosphorous doped (ISPD) silicon or Si:C for n-type devices, or in-situ boron doped (ISBD) silicon germanium for p-type devices, at concentrations of about 1×10¹⁹/cm³ to about 3×10²¹/cm³. By “in-situ,” it is meant that the dopant that dictates the conductivity type of the doped layer is introduced during the process step, e.g., epitaxial deposition, which forms the doped layer.

Referring to FIGS. 1B and 1D, an inter-layer dielectric (ILD) layer 114 is deposited to fill in portions on and around the bottom source/drain regions 113. The ILD layer 114 is deposited using deposition techniques such as, for example, CVD, PECVD, RFCVD, PVD, ALD, MBD, PLD, and/or LSMCD, followed by a planarization process, such as, CMP to remove excess portions of the ILD layer 114 deposited on top of the bottom dummy gate portions 111 and gate spacers 109. The ILD layer 114 may comprise, for example, SiOₓ, SiOC, SiOCN or some other dielectric.

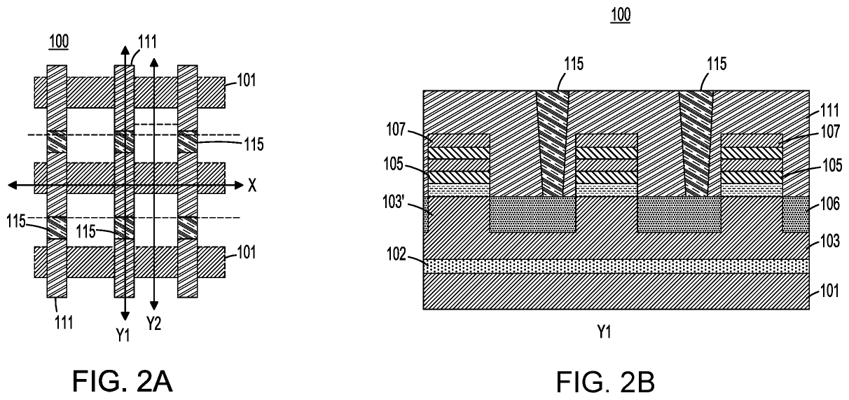

Referring to FIGS. 2A and 2B, parts of the bottom dummy gate portions 111 between the nanosheet stacks comprising the SiGe layers 105 and the Si layers 107 are removed down to the dielectric layer 106 to form trenches in which dielectric material is deposited to form sacrificial dummy gate cut portions 115. The parts of the bottom dummy gate portions 111 are etched using, for example, RIE. The dielectric material of the sacrificial dummy gate cut portions 115 is deposited using deposition techniques such as, for example, CVD, PECVD, RFCVD, PVD, ALD, MBD, PLD, and/or LSMCD, followed by a planarization process, such as, CMP to remove excess portions of the dielectric material deposited on top of the bottom dummy gate portions 111. The dielectric material of the sacrificial dummy gate cut portions 115 may comprise, for example, silicon carbide (SiC), silicon oxycarbide (SiCO) or some other dielectric.

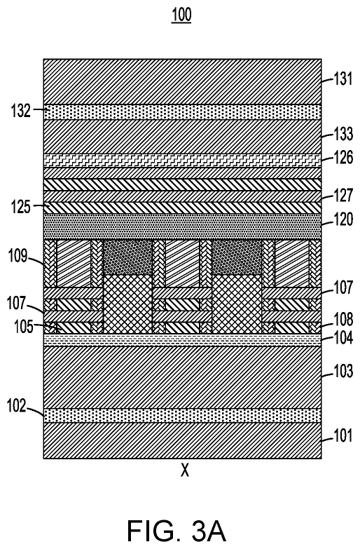

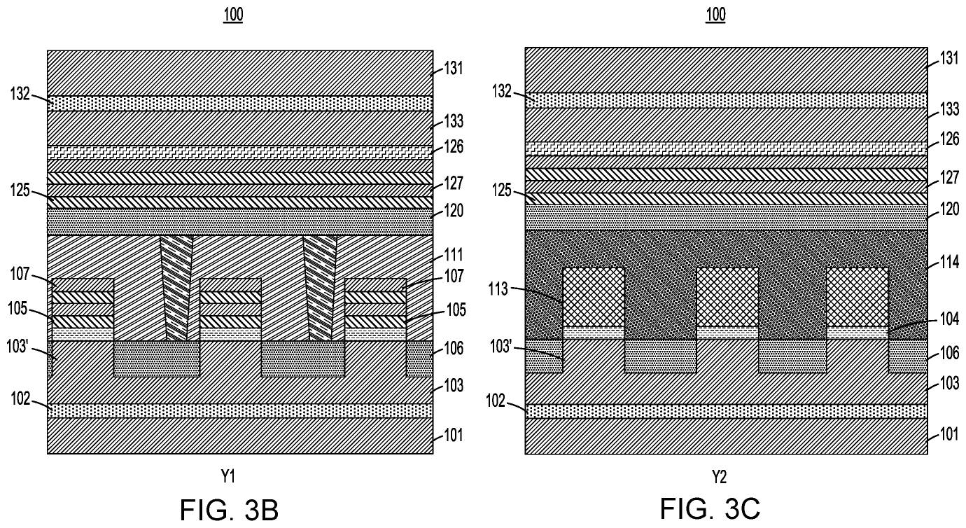

Referring to FIGS. 3A-3C, a bonding dielectric layer 120 is formed on top of the bottom dummy gate portions 111, gate spacers 109, ILD layer 114 and sacrificial dummy gate cut portions 115 formed in the previous steps described in connection with FIGS. 1A-2B. The bonding dielectric layer 120 comprises, for example, an oxide such as, but not necessarily limited to, SiOₓ and is deposited using, for example, an oxide-oxide bonding process.

In an illustrative embodiment, a wafer comprising a substrate 131, etch stop layer 132, semiconductor layer 133, a sacrificial semiconductor layer 126, and alternately stacked SiGe layers 125 and Si layers 127 is bonded to the structure formed in the previous steps described in connection with FIGS. 1A-2B via the bonding dielectric layer 120. In connection with the bonding process, there is an oxide layer (e.g., SiOₓ) (not shown) under the bottom-most SiGe layer 125, and there is another oxide layer (e.g., SiOₓ) (not shown) on the structure formed in the previous steps described in connection with FIGS. 1A-2B. A thermocompression direct bonding process forms the bonding dielectric layer 120. The substrate 131, etch stop layer 132 and semiconductor layer 133 are the same as or similar to the semiconductor substrate 101, etch stop layer 102 and semiconductor layer 103. The alternately stacked SiGe layers 125 and Si layers 127 are the same as or similar to the SiGe layers 105 and Si layers 107 prior to patterning. The sacrificial semiconductor layer 126 comprises, for example, SiGe with a Ge % of 60% (SiGe60).

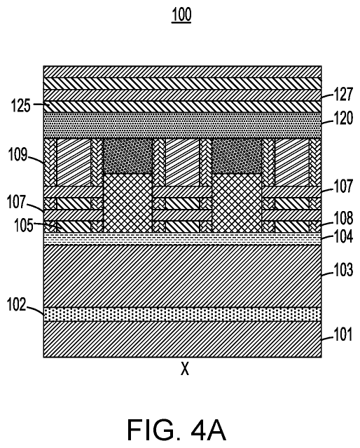

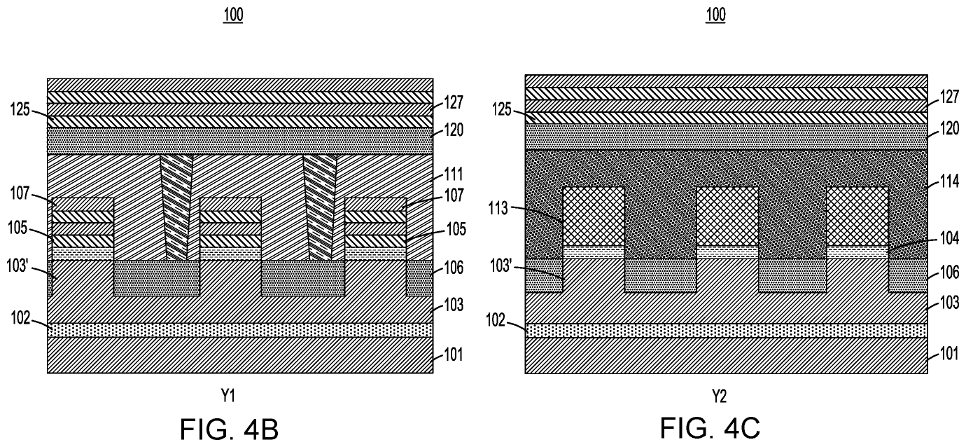

FIGS. 4A-4C illustrate wafer grinding on and semiconductor layer removal from the semiconductor structures 100 of FIGS. 4A-4C. For example, the substrate 131 is removed down to the etch stop layer 132 using, for example, a planarization process such as CMP. The etch stop layer 132 is removed, followed by removal of the semiconductor layer 133 to expose the sacrificial semiconductor layer 126. Etching processes for removal of the etch stop layer 132 include, for example, ion-beam etching (IBE) by Ar/CHF3 based chemistry, and etching processes for removal of the semiconductor layer 133 include, for example, IBE by Ar with SF₆ or Cl₂. The sacrificial semiconductor layer 126 which comprises, for example, SiGe60, is removed using wet etch processes.

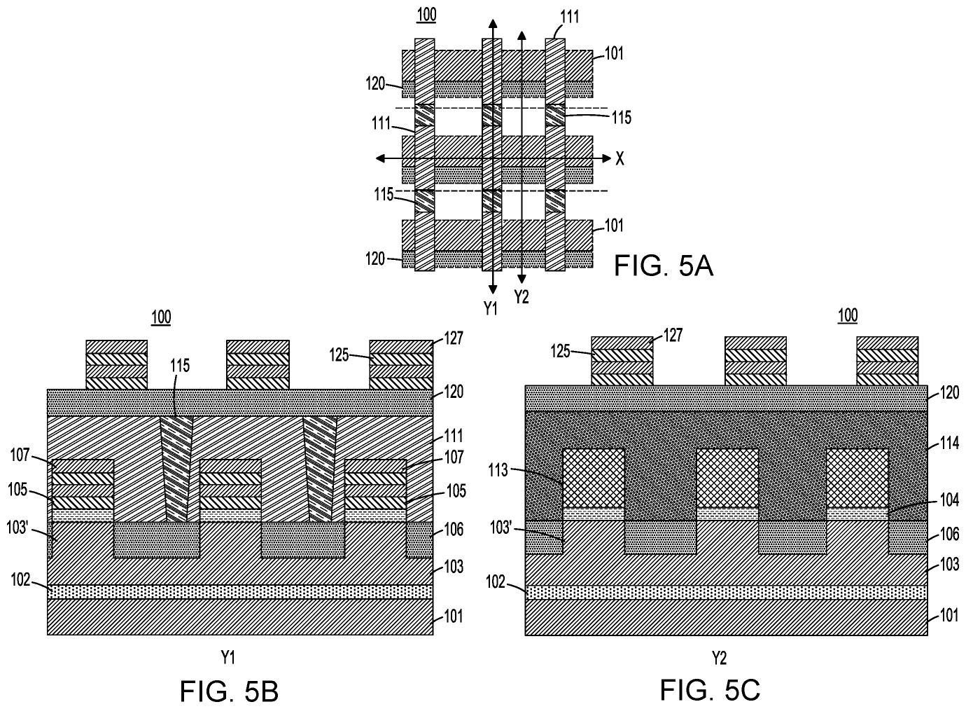

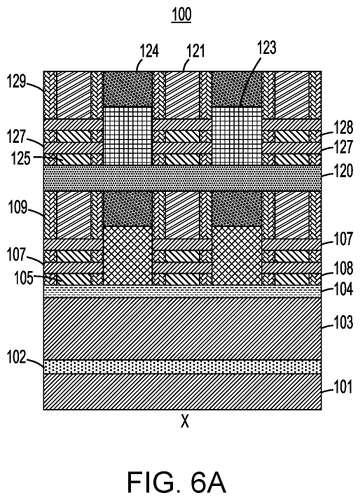

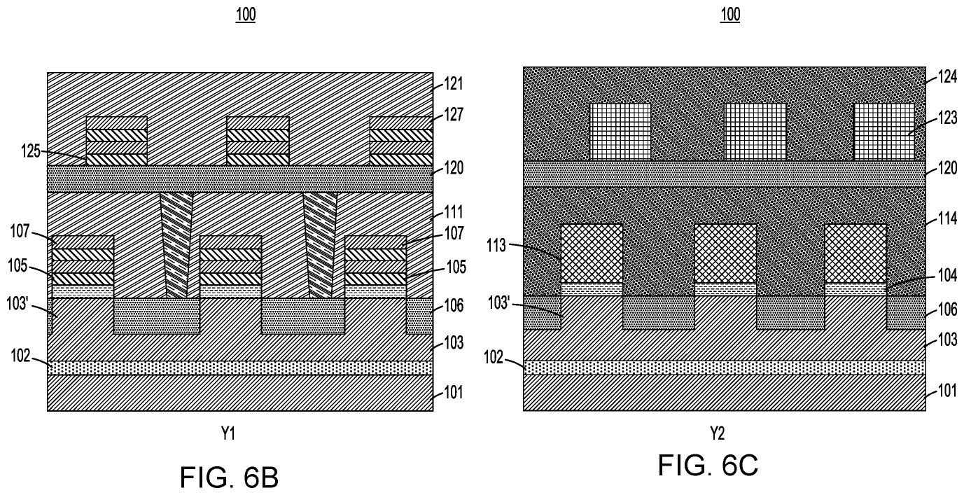

Referring to FIGS. 5A-5C the remaining SiGe layers 125 and Si layers 127 are patterned into nanosheet stacks similar to the stacked nanosheet configurations of the SiGe layers 105 and Si layers 107. As can be seen in FIG. 5B, the resulting nanosheet stacks comprising the SiGe layers 125 and Si layers 127 are stacked over the nanosheet stacks comprising the SiGe layers 105 and Si layers 107 in a staggered configuration. In other words, the nanosheets comprising the SiGe layers 125 and Si layers 127 are patterned such that the resulting nanosheet stacks are offset from the nanosheet stacks comprising the SiGe layers 105 and Si layers 107, and not directly in line with the underlying nanosheet stacks comprising the SiGe layers 105 and Si layers 107. Accordingly, transistors comprising the SiGe layers 125 and Si layers 127 are stacked on transistors comprising the SiGe layers 105 and Si layers 107 in a staggered configuration. The patterning is performed using, for example, masks covering portions of the SiGe layers 125 and Si layers 127, and etching the exposed portions of the SiGe layers 125 and Si layers 127 down to the bonding dielectric layer 120. The masks are positioned to result in the illustrated staggered configuration. As can be seen in FIG. 5C and explained further herein in connection with FIG. 6C, the nanosheet stacks comprising the SiGe layers 125 and Si layers 127 are staggered with respect to the bottom source/drain regions 113, such that top source/drain regions 123 are staggered with respect to the bottom source/drain regions 113.

Referring to FIGS. 6A-6C, top dummy gate portions 121 are formed on the uppermost Si layers 127 and around the stacked nanosheet configurations of the SiGe layers 125 and Si layers 127. Like the bottom dummy gate portions 111, the top dummy gate portions 121 include, but are not necessarily limited to, an amorphous silicon (a-Si) layer, and are deposited using the same or similar techniques as the bottom dummy gate portions 111.

Similar to the SiGe layers 105, lateral etching of the SiGe layers 125 is performed selective to Si layers 127, such that the side portions of the SiGe layers 125 are removed to create vacant areas to be filled in by inner spacers 128. Like the gate spacers 109, gate spacers 129 are positioned on the nanosheet stacks on opposite lateral sides of the top dummy gate portions 121. The gate spacers 129 and inner spacers 128 are formed from the same or similar material and by similar techniques as those of the inner spacers 108 and gate spacers 109.

Like the bottom source/drain regions 113, the top source/drain regions 123 comprise epitaxial layers. The top source/drain regions 123 are grown from sides of the Si layers 127. The conditions of the epitaxial growth and doping processes for the top source/drain regions 123 can be the same as or similar to the conditions for epitaxial growth of the bottom source/drain regions 113.

Referring to FIGS. 6A and 6C, like the ILD layer 114, an ILD layer 124 is deposited to fill in portions on and around the top source/drain regions 123. The ILD layer 124 is deposited using the same or similar techniques as those used in connection with the ILD layer 114, and comprises the same or similar materials as those of the ILD layer 114.

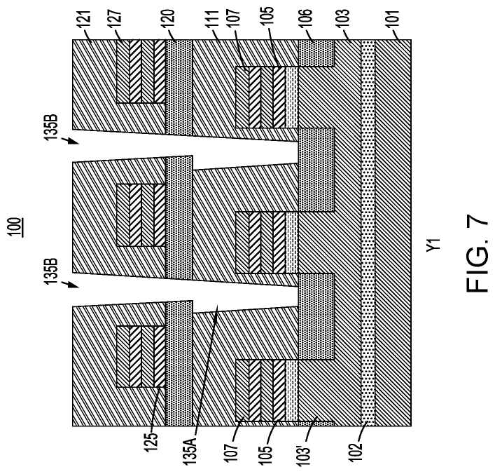

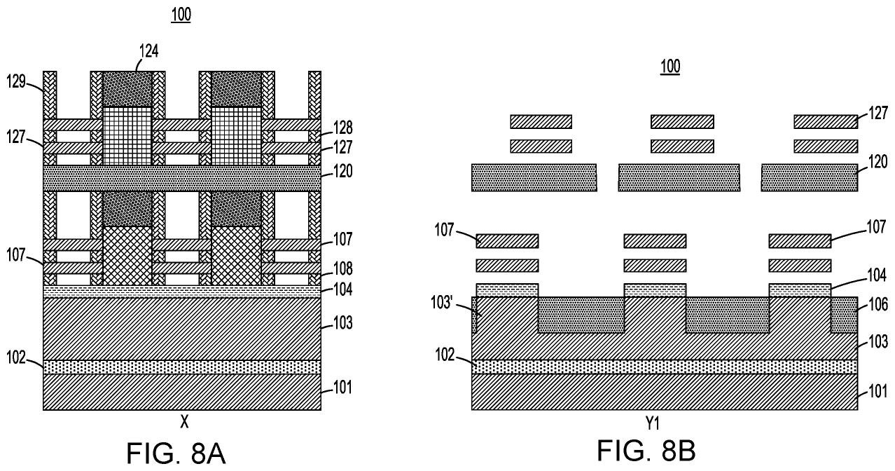

Referring to FIG. 7, gate cut patterning of the top dummy gate portions 121 and removal of the sacrificial material of the sacrificial dummy gate cut portions 115 is shown. As can be seen, trenches 135B are formed through portions of the top dummy gate portions 121 and the bonding dielectric layer 120, which expose part of the top surfaces of the sacrificial dummy gate cut portions 115. The parts of the top dummy gate portions 121 and bonding dielectric layer 120 are etched using, for example, RIE. Following removal of the parts of the top dummy gate portions 121 and bonding dielectric layer 120, the sacrificial material of the sacrificial dummy gate cut portions 115 can be removed using, for example, wet etch processes.

By previously forming the sacrificial dummy gate cut portions 115, minor misalignments between top and bottom gate cut portions are more tolerable compared to opening gate cut trenches in both top and bottom dummy gate portions 121 and 111 in the same removal step since the previously formed sacrificial dummy gate cut portions 115 ensure gate cut portions are formed in a desired area. In other words, if there is a slight misalignment of top and bottom dummy gate portions 121 and 111, bottom dummy gate cut portions can still be opened due to a wet removal of sacrificial dummy gate cut portions 115. In addition, by previously forming the sacrificial dummy gate cut portions 115, a high aspect ratio etch (height:width) that would be needed in a single removal step of the top and bottom dummy gate portions 121 and 111 can be avoided.

Referring to FIGS. 8A and 8B, the top and bottom dummy gate portions 121 and 111 are selectively removed to create vacant areas where gate structures will be formed in place of the top and bottom dummy gate portions 121 and 111. The selective removal can be performed using, for example hot ammonia to remove a-Si. In addition, the SiGe layers 105 and 125 are selectively removed to create vacant areas where gate structures will be formed in place of the SiGe layers 105 and 125. The SiGe layers 105 and 125 are selectively removed with respect to the Si layers 107. The selective removal can be performed using, for example, a dry HCl etch.

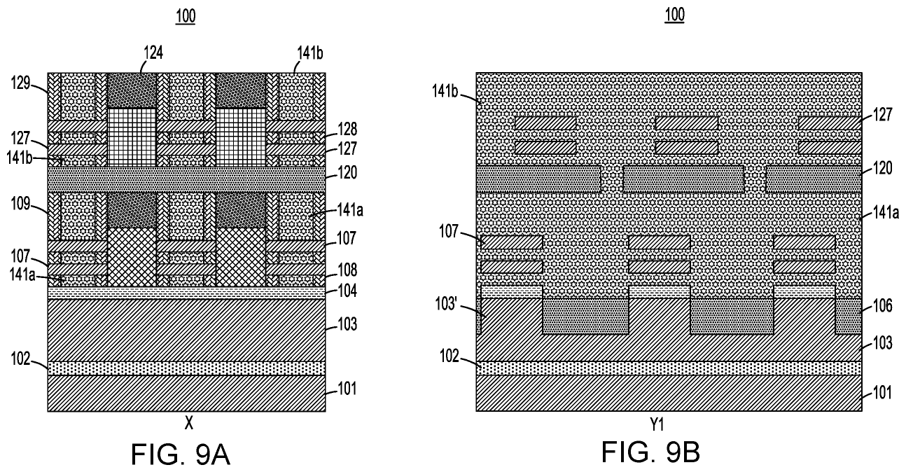

Referring to FIGS. 9A and 9B, following removal of the top and bottom dummy gate portions 121 and 111 and SiGe layers 105 and 125, the Si layers 107 and 127 are suspended, and top and bottom gate regions 141b and 141a, including, for example, gate and dielectric portions are formed in the vacant portions left by removal of the top and bottom dummy gate portions 121 and 111, and the SiGe layers 105 and 125. In illustrative embodiments, each bottom and top gate region 141a and 141b includes a gate dielectric layer such as, for example, a high-K dielectric layer including, but not necessarily limited to, HfO₂ (hafnium oxide), ZrO₂ (zirconium dioxide), hafnium zirconium oxide, Al₂O₃ (aluminum oxide), and Ta₂O₅ (tantalum oxide). Examples of high-k materials also include, but are not limited to, metal oxides such as hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate. According to an embodiment, the bottom and top gate regions 141a and 141b each include a metal gate portion including a work-function metal (WFM) layer, including but not necessarily limited to, for a pFET, titanium nitride (TiN), tantalum nitride (TaN) or ruthenium (Ru), and for an nFET, TiN, titanium aluminum nitride (TiAlN), titanium aluminum carbon nitride (TiAlCN), titanium aluminum carbide (TiAlC), tantalum aluminum carbide (TaAlC), tantalum aluminum carbon nitride (TaAlCN) or lanthanum (La) doped TiN, TaN, which can be deposited on the gate dielectric layer. The metal gate portions can also each further include a gate metal layer including, but not necessarily limited to, metals, such as, for example, tungsten, cobalt, zirconium, tantalum, titanium, aluminum, ruthenium, copper, metal carbides, metal nitrides, transition metal aluminides, tantalum carbide, titanium carbide, tantalum magnesium carbide, or combinations thereof deposited on the WFM layer and the gate dielectric layer. The metal gate portions. It should be appreciated that various other materials may be used for the metal gate portions as desired.

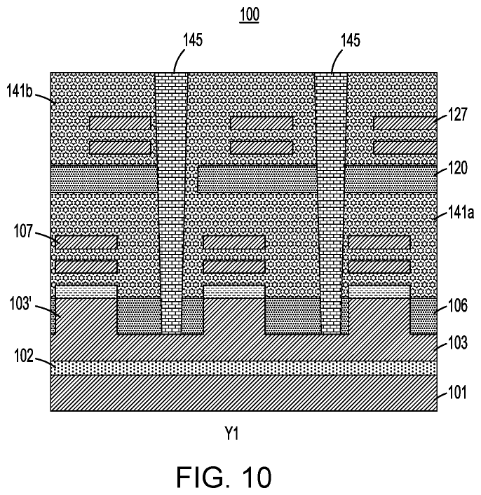

Referring to FIG. 10, parts of the bottom and top gate regions 141a and 141b between the stacks comprising the Si layers 107, 127 and bottom and top gate regions 141a and 141b that replaced the SiGe layers 105, 125 are removed down to the dielectric layer 106, and the exposed portions of the dielectric layer 106 are also removed down to the semiconductor layer 103 to form trenches in which dielectric material is deposited to form gate cut portions 145. Although openings already exist in the bonding dielectric layer 120, additional parts of the bonding dielectric layer 120 may also be removed to form the trenches. The parts of the bottom and top gate regions 141a and 141b are etched using, for example, RIE. The exposed portions of the dielectric layer 106 are etched using, for example, RIE. The dielectric material of the gate cut portions 145 is deposited using deposition techniques such as, for example, CVD, PECVD, RFCVD, PVD, ALD, MBD, PLD, and/or LSMCD, followed by a planarization process, such as, CMP to remove excess portions of the dielectric material deposited on top of the top gate regions 141b. The dielectric material of the gate cut portions 145 may comprise, for example, SiOₓ, SiN or some other dielectric.

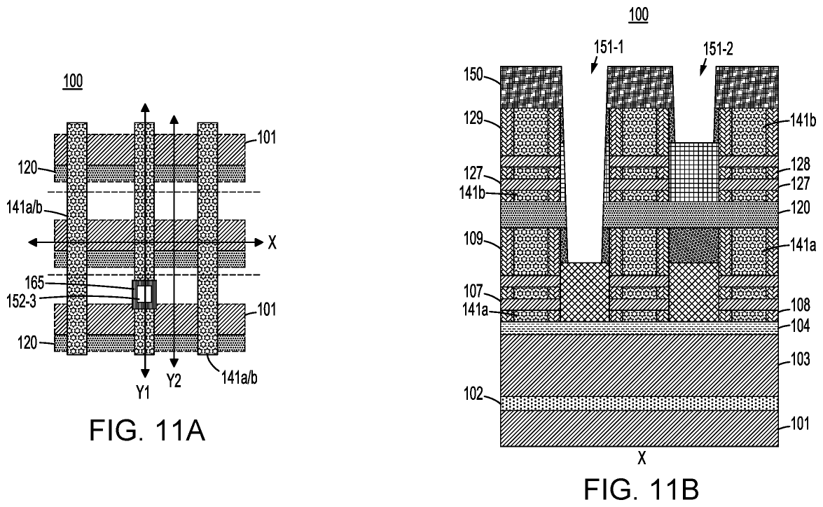

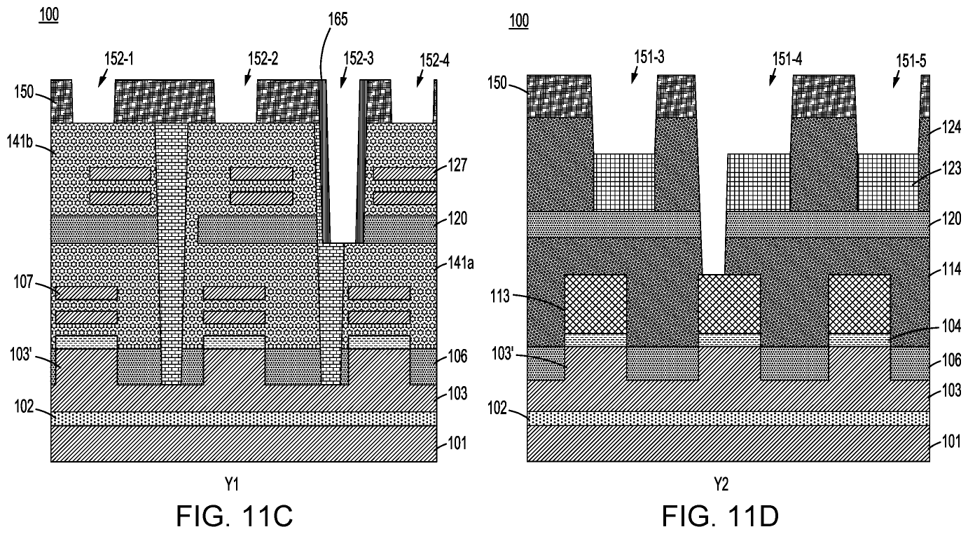

Referring to FIGS. 11A-11D, via openings for gate and source/drain contacts are formed following formation of the gate cut portions 145. In more detail, portions of the semiconductor structure are masked (e.g., with a hardmask (not shown)). At an unmasked portion corresponding to where a gate contact to a bottom gate region 141a of is to be formed, a via opening 152-3 is formed through part of a gate cut portion 145, part of a top gate region 141b and part of the bonding dielectric layer 120 to expose part of a bottom gate region 141a (see FIG. 11C). The via opening 152-3 is formed using, for example, RIE. A dielectric liner layer 165 comprising, for example, SiN, is formed on the sides of the via opening 152-3 on part of a remaining portion of the gate cut portion 145 and on a side of part of the top gate region 141b and part of the bonding dielectric layer 120 adjacent the via opening 152-3. The dielectric liner layer 165 can be deposited using, for example, a conformal deposition process, and horizontal portions of the dielectric liner layer 165 can be removed using, for example, RIE process.

Then, following removal of the hardmask, an ILD layer 150 is formed on the semiconductor structure 100 followed by a CMP process. Then lithography layers are formed (not shown) to pattern via openings for gate and source/drain contacts. In more detail, referring to FIG. 11C, portions of the ILD layer 150 are removed to form via openings 152-1, 152-2 and 152-4 where gate contacts to top gate regions 141b are to be formed. The removal of the ILD layer 150 at these areas exposes portions of the top gate regions 141b. In addition, referring to FIGS. 11B and 11D, portions of the ILD layer 150 are removed in areas where via openings 151-1, 151-2, 151-3, 151-4 and 151-5 (collectively “via openings 151”) are formed. The via openings 151 correspond to where top and bottom source/drain contacts are to be formed. The via openings 151-1 and 151-4 are formed through portions of the ILD layers 124 and 114, top source/drain regions 123 and the bonding dielectric layer 120. The via opening 151-1 exposes a bottom source/drain region 113 and the via opening 151-4 exposes a top source/drain region 123 and a bottom source/drain region 113. The via openings 151-2, 151-3 and 151-5 are formed through the part of the ILD layer 124 to expose a top source/drain region 123. The via openings 151 may be formed using, for example, a dry etching process using a RIE or ion beam etch (IBE) process, a wet chemical etch process or a combination of these etching processes. A dry etch may be performed using a plasma. Plasma systems can operate in several modes by adjusting the parameters of the plasma. Ion milling, sputter etching or RIE bombards the wafer with energetic ions of noble gases that approach the wafer approximately from one direction, and therefore, these processes are an anisotropic or a directional etching process. Such wet or dry etch processes include, for example, IBE by Ar/CHF3 based chemistry. The lithography layers are ashed off following patterning of the via openings 151 and 152.

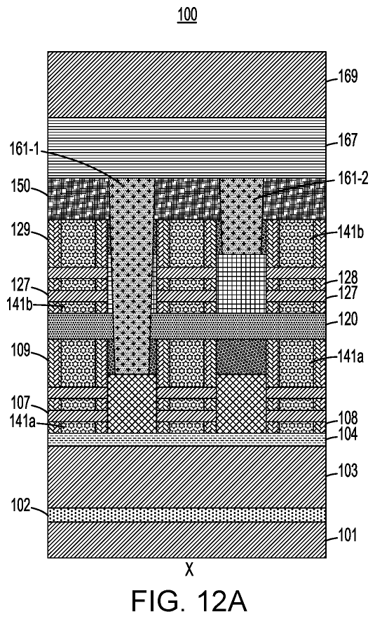

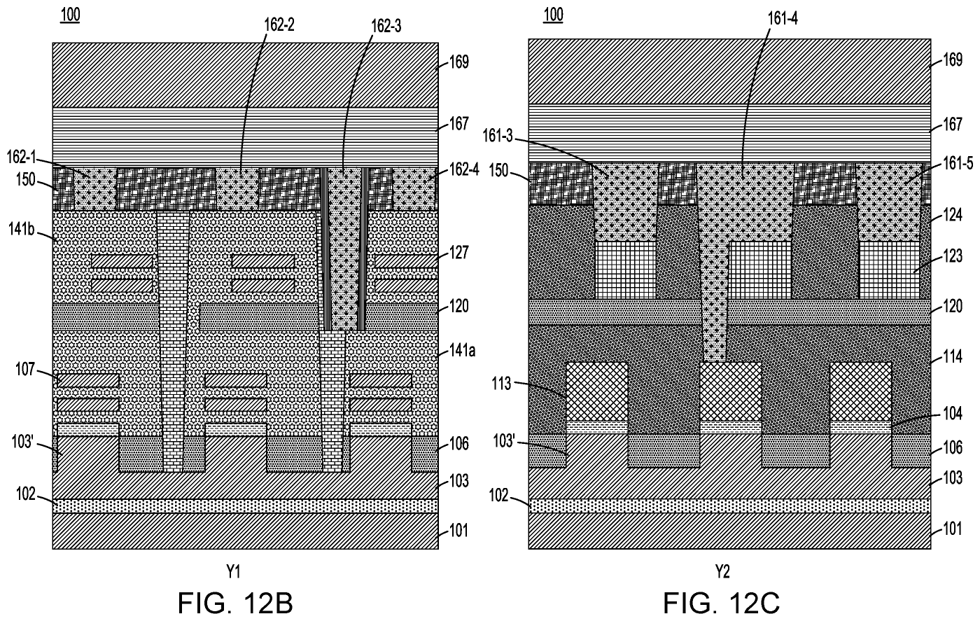

Referring to FIGS. 12A-12C, source/drain contacts 161-1, 161-2, 161-3, 161-4 and 161-5 (collectively “source/drain contacts 161”) are formed in the via openings 151-1, 151-2, 151-3, 151-4 and 151-5, respectively, and gate contacts 162-1, 162-3, 162-3 and 162-4 (collectively “gate contacts 162”) are formed in the via openings 152-1, 152-3, 152-3 and 152-4, respectively. As can be seen in FIGS. 12A and 12C, the source/drain contacts 161-2, 161-3 and 161-5 are to top source/drain regions 123, the source/drain contact 161-1 is to a bottom source/drain region 113 and the source/drain contact 161-4 is to both a top source/drain region 123 and a bottom source/drain region 113. As can be seen in FIG. 12B, the gate contact 162-1 is formed on and contacts a top gate region 141b, which is isolated from the underlying bottom gate region 141a by the bonding dielectric layer 120 and the gate cut portion 145. As can be seen, an edge of the bonding dielectric layer 120 is bordered by the left gate cut portion 145 in FIG. 12B to isolate the top gate region 141b from the underlying bottom gate region 141a.

The gate contact 162-2 is formed on and contacts another top gate region 141b which, as can be seen by the opening in the bonding dielectric layer 120, is not isolated from its underlying bottom gate region 141a. Accordingly, unlike the gate contact 162-1, the gate contact 162-2 is electrically connected to its corresponding top gate region 141b and to the underlying bottom gate region 141a through the corresponding top gate region 141b. The bonding dielectric layer 120 for this pair of top and bottom gate regions 141b and 141a does not extend an entire width between the pair of top and bottom gate regions 141b and 141a, as it is spaced apart from the gate cut portion 145.

The gate contact 162-3 is formed through a part of the right gate cut portion 145 in FIG. 12B along the side of a top gate region 141b to contact the underlying bottom gate region 141a. Due to the presence of the dielectric liner layer 165 between the top gate region 141b and the gate contact 162-3, the gate contact 162-3 is electrically connected to the underlying bottom gate region 141a without being electrically connected to the top gate region 141b of this pair of gate regions. In other words, the dielectric liner layer 165 electrically isolates the top gate region 141b from the gate contact 162-3. In addition, the dielectric liner layer 165 extends to be formed between the bonding dielectric layer 120 and a bottom portion of the gate contact 162-3 so that the combination of the dielectric liner layer 165 and the bonding dielectric layer 120 isolate the rightmost top gate region 141b in FIG. 12B from its underlying bottom gate region 141a. The gate contact 162-4 is formed on and contacts the rightmost top gate region 141b in FIG. 12B, which as explained hereinabove is electrically isolated from its underlying bottom gate region 141a.

The source/drain contacts 161 and gate contacts 162 comprise, for example, a conductor such as, but not necessarily limited to, copper, tungsten, cobalt, ruthenium, etc., and can be deposited using, for example, a deposition technique such as CVD, PECVD, RFCVD, PVD, ALD, MBD, PLD, LSMCD, sputtering and/or plating. The source/drain contacts 161 and gate contacts 162 may be referred to herein as Middle-of-line (MOL) contacts.

FIGS. 12A-12C further illustrate frontside BEOL interconnects 167 formed on the ILD layer 150 including the source/drain contacts 161 and gate contacts 162. A carrier wafer 169 is bonded to the frontside BEOL interconnects 167. The frontside BEOL interconnects 167 include various BEOL interconnect structures. The carrier wafer 169 may be formed of materials similar to that of the semiconductor substrate 101, and may be formed over the frontside BEOL interconnects 167 using a wafer bonding process, such as dielectric-to-dielectric bonding.

FIGS. 13A-13C are schematic cross-sectional views illustrating semiconductor structure rotation, substrate, etch stop layer and semiconductor layer removal and backside ILD layer deposition following contact metallization, BEOL formation and carrier wafer bonding. Using the carrier wafer 169, the FIG. 12A, 12B and FIG. 12C structures may be “flipped” (e.g., rotated 180 degrees) so that the structures are inverted. In addition, the semiconductor substrate 101 is removed from the back side. The removal process, which comprises etching of the semiconductor substrate 101, stops at the etch stop layer 102. For example, the semiconductor substrate 101 is selectively etched with an etchant that selectively etches silicon with respect to a material of the etch stop layer 102 (e.g., SiO₂ or SiGe).

The etch stop layer 102 is removed, followed by removal of the semiconductor layer 103 to expose portions of the dielectric layers 104 and 106, and the gate cut portions 145. Etching processes for removal of the etch stop layer 102 include, for example, IBE by Ar/CHF3 based chemistry, and etching processes for removal of the semiconductor layer 103 include, for example, IBE by Ar with SF₆ or Cl₂. A backside ILD layer 170 is deposited which fills in portions left vacant following removal of the semiconductor layer 103. The backside ILD layer 170 comprises the same or similar material to that of the ILD layers 114 and 124, and is deposited using one or more deposition techniques used for depositing the ILD layers 114 and 124, followed by a planarization process such as, for example, CMP.

FIGS. 14A-14C are schematic cross-sectional views illustrating backside contact and power delivery network layer formation. Backside contacts 171-1, 171-2 and 171-3 (also referred to herein as “power rails” or “power elements”) are formed in the backside ILD layer 170 by forming trenches in the backside ILD layer 170 and filling the trenches with conductive material. Trenches are respectively opened in the backside ILD layer 170 using, for example, lithography followed by RIE. The backside contacts 171-1, 171-2 and 171-3 are formed in the trenches by filling the trenches with conductive material, such as, for example, electrically conductive material including, but not necessarily limited to, tungsten, cobalt, zirconium, tantalum, titanium, aluminum, ruthenium, and/or copper. A liner layer (not shown) including, for example, titanium and/or titanium nitride, may be formed on side and bottom surfaces of the trenches before filling the trenches with the conductive material. Deposition of the conductive material can be performed using one or more deposition techniques, including, but not necessarily limited to, CVD, PECVD, PVD, ALD, MBD, PLD, LSMCD, and/or spin-on coating, followed by planarization using a planarization process, such as, for example, CMP.

The backside contacts 171-1, 171-2 and 171-3 deliver, for example, drain voltage (VDD) or source voltage (VSS) to their corresponding bottom source/drain regions 113. Backside power delivery network (BSPDN) layers 172 are formed on the on the backside ILD layer 170 including the backside contacts 171-1, 171-2 and 171-3. The backside power delivery network layers 172 include various BSPDN structures such as, but not necessarily limited to, interconnects in a power supply path from voltage regulator modules (VRMs) to circuits. The interconnects can comprise, for example, power and ground planes in circuit boards, cables, connectors and capacitors associated with a power supply. Backside power delivery prevents BEOL routing congestion, resulting in power performance benefits.

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, CMOSs, MOSFETS, and/or FinFETs. By way of non-limiting example, the semiconductor devices can include, but are not limited to CMOS, MOSFET, and FinFET devices, and/or semiconductor devices that use CMOS, MOSFET, and/or FinFET technology.

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor. An example integrated circuit includes one or more semiconductor devices with the above-described contact configurations and transistors stacked in a staggered configuration.

As noted above, illustrative embodiments correspond to methods for forming contact structures for a stacked semiconductor device where configurations of gate cut portions and dielectric layers control gate contact connections to gate regions of stacked transistors, along with illustrative apparatus, systems and devices formed using such methods. The transistors stacked in a staggered configuration and configurations of the gate contacts for strategically electrically isolated and exposed gate regions allow for enhanced gate control when compared with conventional structures. As a result, increased transistor control can be achieved while maintaining the same or smaller footprints.

It should be understood that the various layers, structures, and regions shown in the figures are schematic illustrations that are not drawn to scale. In addition, for ease of explanation, one or more layers, structures, and regions of a type commonly used to form semiconductor devices or structures may not be explicitly shown in a given figure. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

Moreover, the same or similar reference numbers are used throughout the figures to denote the same or similar features, elements, or structures, and thus, a detailed explanation of the same or similar features, elements, or structures are not repeated for each of the figures. It is to be understood that the terms “approximately” or “substantially” as used herein with regard to thicknesses, widths, percentages, ranges, temperatures, times and other process parameters, etc., are meant to denote being close or approximate to, but not exactly. For example, the term “approximately” or “substantially” as used herein implies that a small margin of error is present, such as +5%, preferably less than 2% or 1% or less than the stated amount.

In the description above, various materials, dimensions and processing parameters for different elements are provided. Unless otherwise noted, such materials are given by way of example only and embodiments are not limited solely to the specific examples given. Similarly, unless otherwise noted, all dimensions and process parameters are given by way of example and embodiments are not limited solely to the specific dimensions or ranges given.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor device, comprising:
a first transistor comprising a first gate region;
a second transistor comprising a second gate region, wherein the second transistor is stacked on the first transistor in a staggered configuration;
a dielectric bonding layer between the first transistor and the second transistor;
a gate cut portion along a side of the first gate region and a side of the second gate region; and
a gate contact connected to at least one of the first gate region and the second gate region.

2. The semiconductor device of claim 1, wherein the gate cut portion contacts the side of the first gate region and the side of the second gate region.

3. The semiconductor device of claim 1, wherein the gate contact is electrically connected to the first gate region through the second gate region.

4. The semiconductor device of claim 1, wherein the dielectric bonding layer is disposed between a portion of the first gate region and a portion the second gate region without being disposed between a remaining portion of the first gate region and a remaining portion the second gate region.

5. The semiconductor device of claim 1, wherein the dielectric bonding layer is spaced apart from the gate cut portion.

6. The semiconductor device of claim 1, wherein the gate contact is electrically connected to the first gate region without being electrically connected to the second gate region.

7. The semiconductor device of claim 6, wherein the gate contact is formed through a part of the gate cut portion along the side of the second gate region to contact the first gate region.

8. The semiconductor device of claim 7, further comprising a dielectric liner layer on a side of the gate contact between the second gate region and the gate contact.

9. The semiconductor device of claim 8, wherein the gate contact extends along a side of the dielectric bonding layer to contact the first gate region, and wherein the dielectric liner layer is further on a side of the gate contact between the dielectric bonding layer and the gate contact.

10. The semiconductor device of claim 1, wherein:
the gate contact is on and contacts the second gate region; and
the first gate region is electrically isolated from the second gate region by the dielectric bonding layer and the gate cut portion.

11. The semiconductor device of claim 1, wherein the gate cut portion contacts an edge of the dielectric bonding layer.

12. A semiconductor device, comprising:
a first pair of transistors, wherein the first pair of transistors comprises a second transistor stacked on a first transistor in a staggered configuration, and wherein the first transistor comprises a first gate region and the second transistor comprises a second gate region;
a second pair of transistors, wherein the second pair of transistors comprises a fourth transistor stacked on a third transistor in a staggered configuration, and wherein the third transistor comprises a third gate region and the fourth transistor comprises a fourth gate region;
a first gate contact electrically connected to the first gate region and the second gate region;
a second gate contact electrically connected to the third gate region; and
a third gate contact electrically connected to the fourth gate region.

13. The semiconductor device of claim 12, further comprising:
a dielectric bonding layer between the first gate region and the second gate region and between the third gate region and the fourth gate region; and
a gate cut portion between the first pair and the second pair of transistors, wherein the gate cut portion is formed through the dielectric bonding layer.

14. The semiconductor device of claim 13, wherein the second gate contact is formed through a part of the gate cut portion along a side of the fourth gate region to contact the third gate region.

15. The semiconductor device of claim 14, further comprising a dielectric liner layer on a side of the second gate contact between the fourth gate region and the second gate contact.

16. The semiconductor device of claim 13, wherein:
the first gate contact is on the second gate region and is electrically connected to the first gate region through the second gate region; and
the dielectric bonding layer is disposed between a portion of the first gate region and a portion the second gate region without being disposed between a remaining portion of the first gate region and a remaining portion the second gate region

17. A semiconductor device, comprising:
a first transistor comprising a first gate region;
a second transistor comprising a second gate region, wherein the second transistor is stacked on the first transistor in a staggered configuration;
a dielectric bonding layer between the first transistor and the second transistor;
a dielectric trench along a side of the first gate region and a side of the second gate region; and
at least one gate contact contacting one of the first gate region and the second gate region.

18. The semiconductor device of claim 17, wherein the at least one gate contact is on and contacts the second gate region and is electrically connected to the first gate region through the second gate region.

19. The semiconductor device of claim 17, wherein the at least one gate contact is formed through a part of the dielectric trench along the side of the second gate region to contact the first gate region, and a dielectric liner layer is on a side of the at least one gate contact between the second gate region and the at least one gate contact.

20. The semiconductor device of claim 17, wherein:
the at least one gate contact is on and contacts the second gate region; and
the first gate region is electrically isolated from the second gate region by the dielectric bonding layer and the dielectric trench.
